(19) United States
(12) Patent Application Publication
(10) Pub. No.: US 2014/0070177 A1
(43) Pub. Date: Mar. 13, 2014

(54) ORGANIC ELECTROLUMINESCENT DISPLAY AND METHOD OF MANUFACTURING THE SAME

(71) Applicant: SAMSUNG DISPLAY CO., LTD., Yongin-si (KR)

(72) Inventors: Jong Yun Kim, Yongin-si (KR); Youngdae Kim, Yongin-si (KR)

(73) Assignee: SAMSUNG DISPLAY CO., LTD., Yongin-si (KR)

(21) Appl. No.: 13/792,031

(22) Filed: Mar. 9, 2013

(30) Foreign Application Priority Data
Sep. 10, 2012 (KR) 10-2012-0099937

(51) Int. Cl. H01L 27/32

(52) U.S. Cl. CPC H01L 27/3258
USPC 257/40; 257/88; 438/34

(57) ABSTRACT

An organic electroluminescent display includes: a substrate having a plurality of pixel areas and a non-pixel area; pixel electrodes located at respective ones of the pixel areas; driving transistors electrically connected to respective ones of the pixel electrodes; an insulating cover layer covering the driving transistors and having a dummy well located at a portion of the insulating cover layer corresponding to the non-pixel area; a pixel definition layer on the insulating cover layer and having openings therethrough corresponding to the pixel areas, respectively; an organic light emitting layer on the pixel electrodes; and a common electrode on the organic light emitting layer. A portion of the pixel definition layer fills the dummy well.

### CROSS-REFERENCE TO RELATED APPLICATION

This U.S. non-provisional patent application claims priority under 35 U.S.C. §119 and the benefit of Korean Patent Application No. 10-2012-0099937, filed on Sep. 10, 2012, the entire contents of which are hereby incorporated by reference.

### BACKGROUND

1. Field of Disclosure

The present disclosure relates to an organic electroluminescent display and a method of manufacturing the same.

2. Description of the Related Art

An organic electroluminescent display includes an anode electrode, a cathode electrode, and an organic light emitting layer interposed between the anode electrode and the cathode electrode. The organic electroluminescent display displays an image using light emitted from the organic light emitting layer.

Among elements of the organic electroluminescent display, the anode and cathode electrodes are typically formed by using processes widely used to manufacture a liquid crystal display. The organic light emitting layer, however, is formed using an evaporation process and a thermal transfer printing process, which are not typically used to manufacture the liquid crystal display. A production yield and a display quality of the organic electroluminescent display may depend on the processes applied to form the organic light emitting layer.

### SUMMARY

The present disclosure provides an organic electroluminescent display capable of forming an organic light emitting layer to have a structure using a pixel definition layer.

The present disclosure provides a method of manufacturing the organic electroluminescent display.

Embodiments of the present invention provide an organic electroluminescent display including a substrate, pixel electrodes, driving transistors, an insulating cover layer, a pixel definition layer, an organic light emitting layer, and a common electrode.

The substrate has a plurality of pixel areas and a non-pixel area. The pixel electrodes are located at respective ones of the pixel areas, and the driving transistors are electrically connected to respective ones of the pixel electrodes. The insulating cover layer covers the driving transistors and has a dummy well located at a portion of the insulating cover layer corresponding to the non-pixel area.

The pixel definition layer is on the insulating cover layer and has openings formed therethrough corresponding to the pixel areas, respectively, and a portion of the definition layer fills the dummy well. The organic light emitting layer is on the pixel electrodes, and the common electrode is on the organic light emitting layer.

Embodiments of the present invention provide a method of manufacturing an organic electroluminescent display as follows. When a substrate having a plurality of pixel areas and a non-pixel area is prepared, driving transistors are formed on the substrate, and an insulating cover layer is formed on the substrate to cover the driving transistors. The insulating cover layer is provided with via holes to expose a portion of the driving transistors. Then, pixel electrodes are formed at the pixel areas to be electrically connected to respective ones of the driving transistors, and a portion of the insulating cover layer corresponding to the non-pixel area is removed to form a dummy well.

After that, a pixel definition layer is formed on the insulating cover layer, wherein a portion of the pixel definition layer fills the dummy well, and the pixel definition layer has openings to expose at least a portion of the pixel electrodes. Then, an organic light emitting layer is formed on the exposed at least the portion of the pixel electrodes, and a common electrode is formed on the organic light emitting layer.

According to the above, the bank thickness of the pixel definition layer may be controlled to be reduced without lowering the uniformity of the thickness of the pixel definition layer, and thus the organic light emitting layer may be easily formed. For example, according to one embodiment of the present invention, because the step-difference caused by the pixel definition layer is reduced by controlling the bank thickness when the organic light emitting layer is formed using a transfer printing method, the organic light emitting layer may be easily transferred to the substrate.

### BRIEF DESCRIPTION OF THE DRAWINGS

The above and other aspects of the present invention will become readily apparent by reference to the following detailed description when considered in conjunction with the accompanying drawings wherein:

FIG. 1 is a plan view showing a portion of an organic electroluminescent display according to an exemplary embodiment of the present invention;

FIG. 2A is a cross-sectional view taken along the line I-I′ of FIG. 1;

FIG. 2B is a cross-sectional view taken along the line II-II′ of FIG. 1;

FIG. 3 is a cross-sectional view showing an organic electroluminescent display according to another exemplary embodiment of the present invention; and

FIGS. 4A to 4E are cross-sectional views showing a method of manufacturing the organic electroluminescent display shown in FIG. 2A.

### DETAILED DESCRIPTION

It will be understood that when an element or layer is referred to as being “on”, “connected to” or “coupled to” another element or layer, it can be directly on, connected or coupled to the other element or layer or intervening elements or layers may be present. In some embodiments, when an element is referred to as being “directly on,” “directly connected to” or “directly coupled to” another element or layer, there may be no intervening elements or layers present. Like reference numbers refer to like elements throughout. As used herein, the term “and/or” includes any and all combinations of one or more of the associated listed items.

It will be understood that, although the terms first, second, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “over” or “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention or any particular embodiment. As used herein, the singular forms, “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

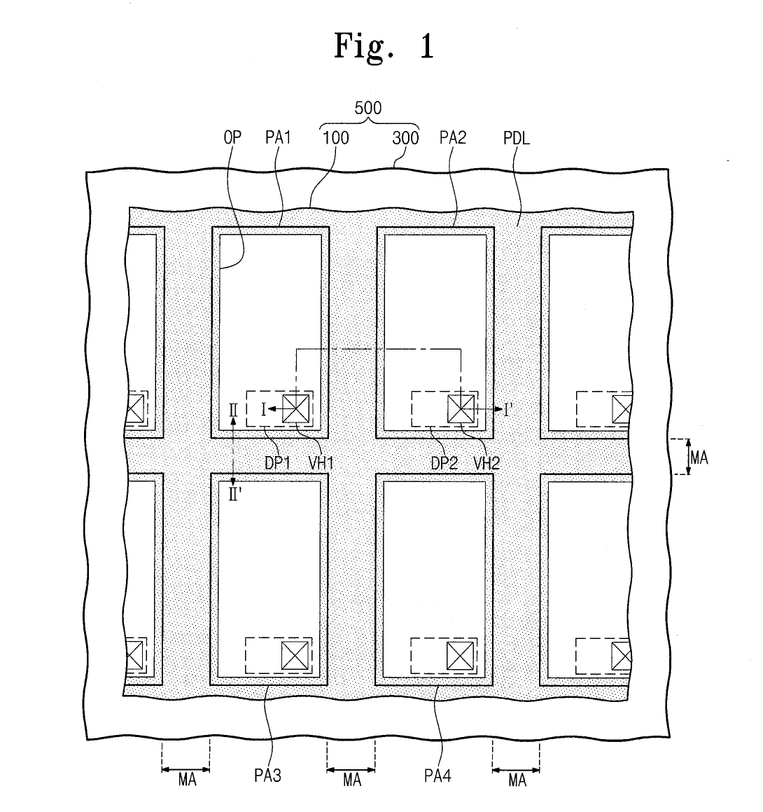

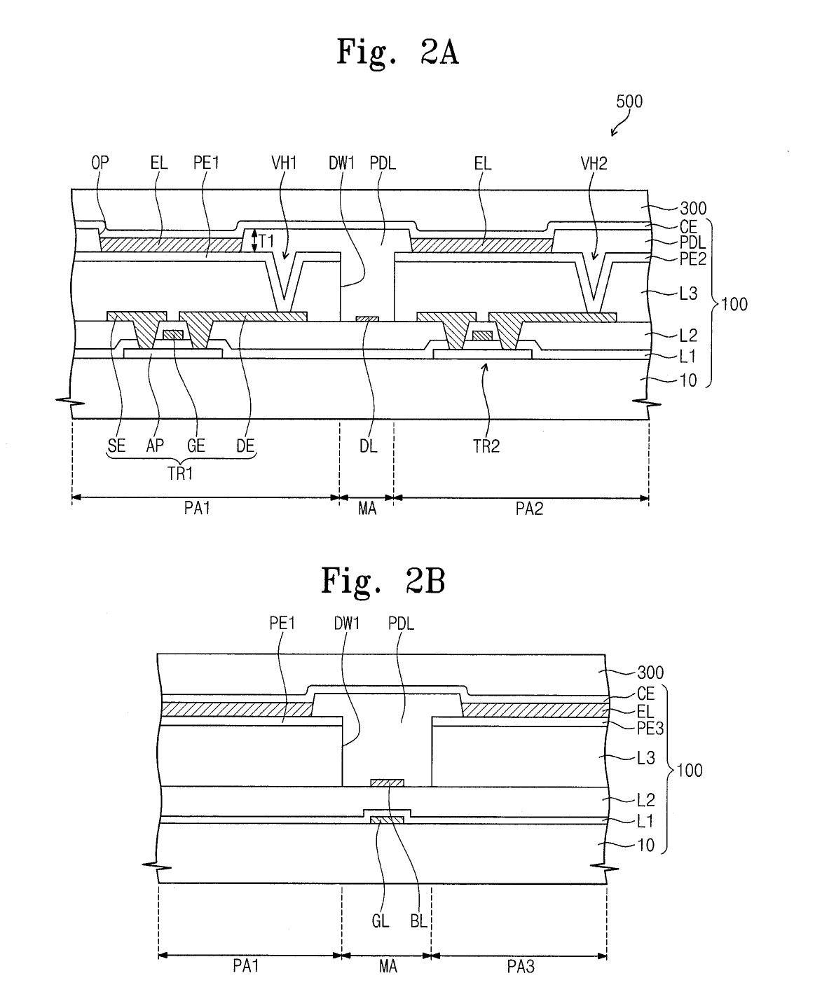

FIG. 1 is a plan view showing a portion of an organic electroluminescent display according to an exemplary embodiment of the present invention. FIG. 2A is a cross-sectional view taken along the line I-I′ of FIG. 1, and FIG. 2B is a cross-sectional view taken along the line II-II′ of FIG. 1. FIG. 1 shows a plurality of pixel areas and a non-pixel area MA of a display substrate 100. Four pixel areas, e.g., first, second, third, and fourth pixel areas PA1, PA2, PA3, and PA4, have been shown in FIG. 1 as a representative example.

Referring to FIGS. 1, 2A, and 2B, the organic electroluminescent display 500 includes the display substrate 100 and an opposite substrate 300 facing the display substrate 100. The display substrate 100 includes the pixel areas and the non-pixel area MA, and the non-pixel area MA is disposed between the pixel areas. Hereinafter, among pixels respectively arranged in the first to fourth pixel areas PA1 to PA4, the pixels arranged in the first and second pixel areas PA1 and PA2 will be described as an example.

The display substrate 100 includes a substrate 10, a first driver DP1, a second driver DP2, a first pixel electrode PE1, a second pixel electrode PE2, a gate insulating layer L1, an inter-insulating layer L2, an insulating cover layer L3, a pixel definition layer L4, an organic light emitting layer EL, and a common electrode CE.

The first driver DP1 and the second driver DP2 are disposed on the substrate 10. The first driver DP1 includes a first driving transistor TR1 electrically connected to the first pixel electrode PE1 to switch a source voltage applied to the first pixel electrode PE1, and the second driver DP2 includes a second driving transistor TR2 electrically connected to the second pixel electrode PE2 to switch a source voltage applied to the second pixel electrode PE2. Since the first and second driving transistors TR1 and TR2 have substantially the same configuration and function, hereinafter, the first driving transistor TR1 will be described in detail.

The first driving transistor TR1 includes a gate electrode GE, an active pattern AP, a source electrode SE, and a drain electrode DE. The source electrode SE is electrically connected to a source voltage line BL, which is disposed to correspond to the non-pixel area MA, for transmitting the source voltage, and the drain electrode DE is electrically connected to the first pixel electrode PE1. Thus, when the first driving transistor TR1 is turned on, the source voltage is applied to the first pixel electrode PE1 from the source voltage line BL through the turned-on first driving transistor TR1.

In addition, a gate line GL for transmitting a gate signal and a data line DL for transmitting a data signal are disposed in the non-pixel area MA, and the first driver DP1 further includes a switching transistor (not shown) connected to the gate line GL, the data line DL, and the gate electrode GE of the first driving transistor TR1. In this case, the switching transistor is turned on in response to the gate signal, and the data signal from the data line DL is applied to the gate electrode GE of the first driving transistor TR1 through the turned-on switching transistor. Thus, the first driving transistor TR1 is turned on in response to the data signal, and switches the source voltage applied to the first pixel electrode PE1.

The gate insulating layer L1 covers the active pattern AP to insulate the gate electrode GE from the active pattern AP. The inter-insulating layer L2 covers the gate electrode GE of the first driving transistor TR1 to insulate the source and drain electrodes SE and DE from the gate electrode GE.

The insulating cover layer L3 has an insulating property and covers the first and second driving transistors TR1 and TR2. In the present exemplary embodiment, the insulating cover layer L3 may be, but is not limited to, an organic layer and has a thickness sufficient to allow its upper surface to be flat. In addition, the insulating cover layer L3 is provided with first and second via holes VH1 and VH2 formed therethrough. Accordingly, the drain electrode DE of the first driving transistor TR1 is electrically connected to the first pixel electrode PE1 through the first via hole VH1 and the drain electrode DE of the second driving transistor TR2 is electrically connected to the second pixel electrode PE2 through the second via hole VH2.

In addition, the insulating cover layer L3 includes a dummy well DW1 formed by removing a portion thereof corresponding to the non-pixel area MA. Thus, a portion of the pixel definition layer PDL disposed on the insulating cover layer L3 is filled in the dummy well DW1. In the present exemplary embodiment, the dummy well DW1 is formed through the insulating cover layer L3.

The first and second pixel electrodes PE1 and PE2 are disposed on the insulating cover layer L3. The first pixel electrode PE1 is disposed to correspond to the first pixel area PA1 and the second pixel electrode PE2 is disposed corresponding to the second pixel area PA2. Therefore, the first and second pixel electrodes PE1 and PE2 are spaced apart from each other with the non-pixel area MA interposed therebetween.

In addition, as shown in FIG. 2B, a third pixel electrode PE3 is disposed on the insulating cover layer L3 to correspond to the third pixel area PA3. The third pixel electrode PE3 is spaced apart from the first pixel electrode PE1 with the non-pixel area MA interposed between the first and third pixel electrode PE1 and PE3. That is, among the pixel electrodes disposed to correspond to the pixel areas in a one-to-one correspondence, two pixels adjacent to each other are spaced apart from each other with the non-pixel area MA interposed therebetween.

The pixel definition layer PDL is disposed on the insulating cover layer L3. The pixel definition layer PDL is provided with openings OP formed therethrough to respectively correspond to the first and second pixel areas PA1 and PA2. The openings OP are filled with the organic light emitting layer EL, and thus the organic light emitting layer EL is provided on the first pixel electrode PE1 and the second pixel electrode PE2.

Meanwhile, because the pixel definition layer PDL is disposed on the insulating cover layer L3, the portion of the pixel definition layer PDL is filled in the dummy well DW1. Thus, when a thickness of the portion of the pixel definition layer PDL, which is disposed on the insulating cover layer L3, is referred to as a bank thickness T1, the bank thickness T1 may be reduced since the portion of the pixel definition layer PDL is filled in the dummy well DW1.

The organic light emitting layer EL is accommodated in the openings OP formed through the pixel definition layer PDL, and thus disposed on the first and second pixel electrodes PE1 and PE2. In the present exemplary embodiment, the organic light emitting layer EL is disposed in each of the first and second pixel areas PA1 and PA2, but it should not be limited thereto or thereby. That is, the organic light emitting layer EL may be formed over the whole pixel areas and the non-pixel area.

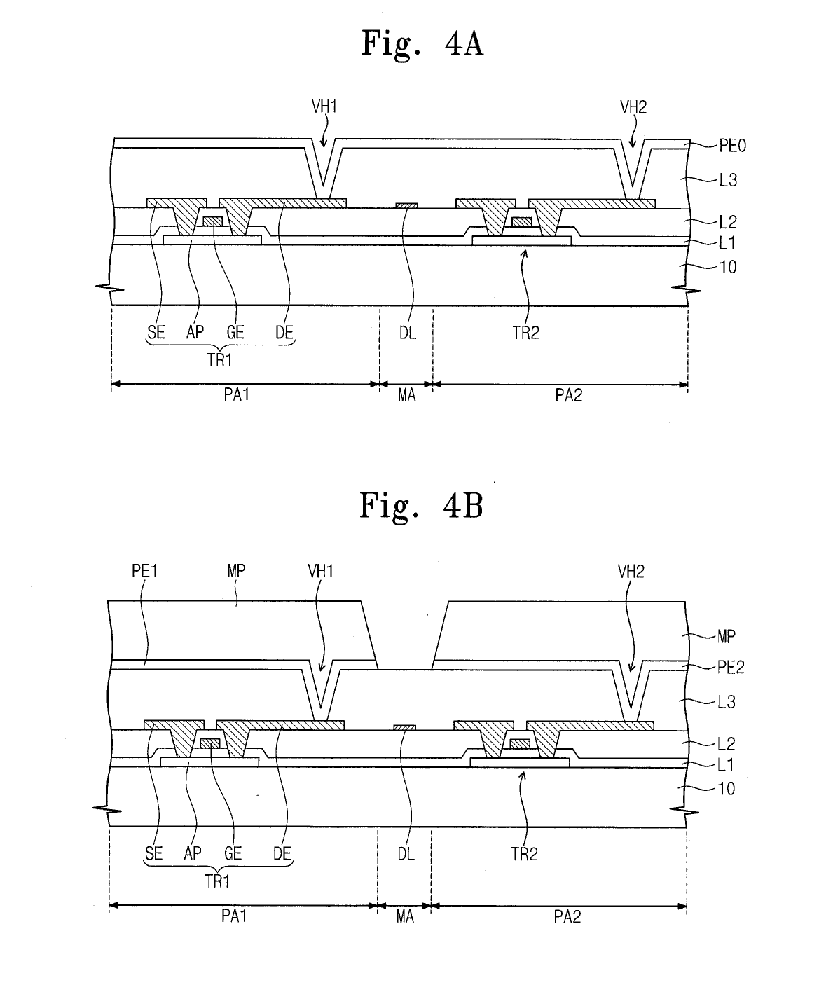

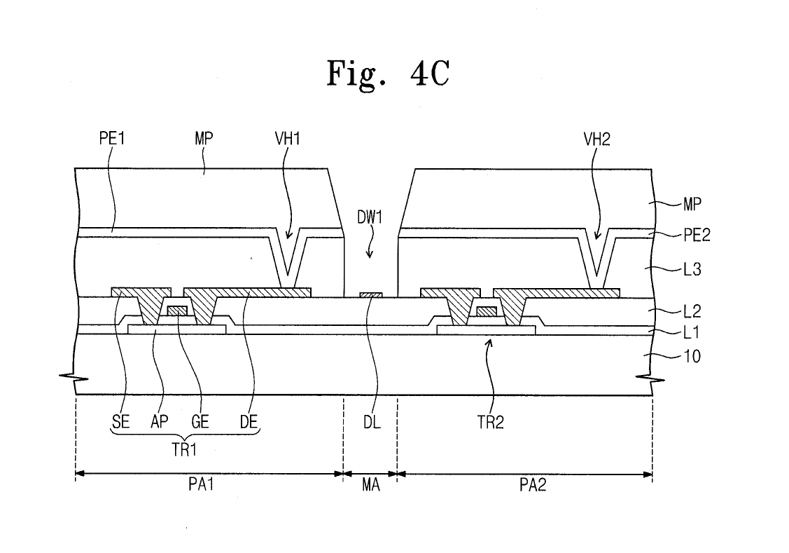

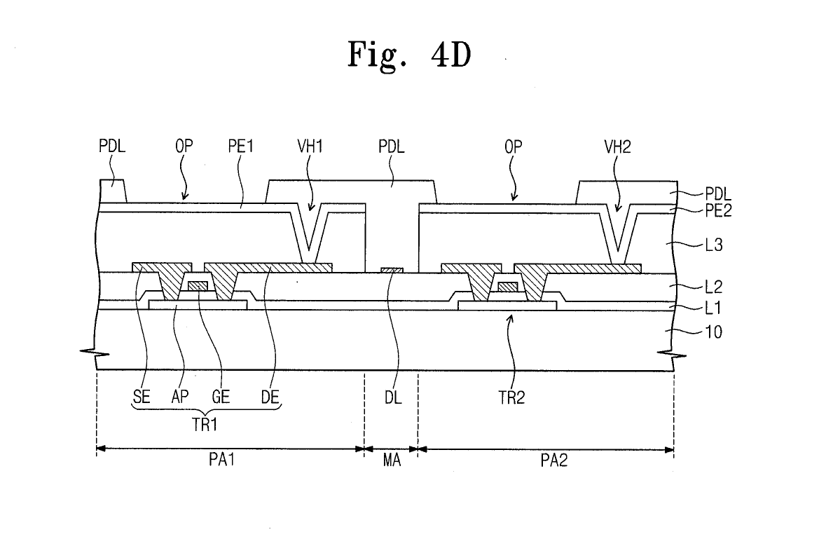

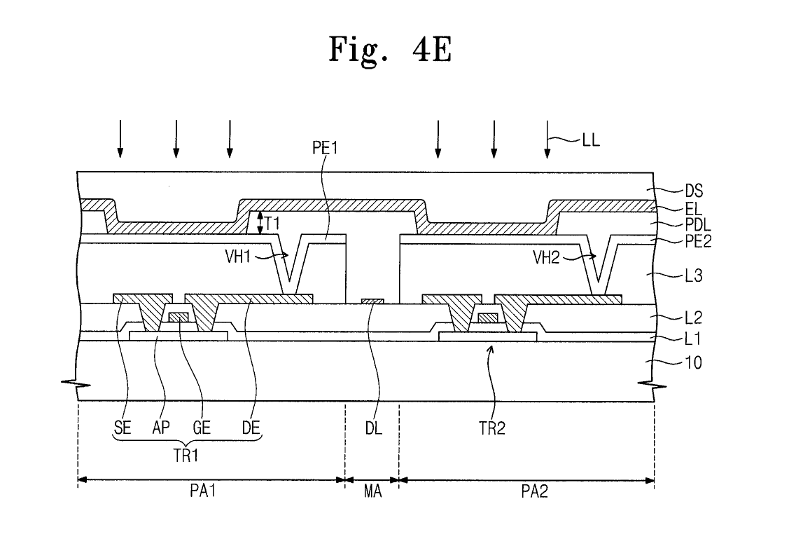

Meanwhile, in the case that the dummy well DW1 is formed through the insulating cover layer L3 in order to reduce the bank thickness T1, the organic light emitting layer EL is easily formed using a transfer printing method in a viewpoint of a manufacturing method. This will be described in detail with reference to FIG. 4E later.

In the present exemplary embodiment, the bank thickness T1 is in a range from about 1,000 angstroms (0.1 μm) to about 3,000 angstroms (0.3 μm). When the bank thickness T1 is less than about 1,000 angstroms, it may not be easy to define the area, in which the organic light emitting layer EL is formed, using the pixel definition layer PDL. In addition, when the bank thickness T1 exceeds about 3,000 angstroms, the transfer printing quality may be lowered due to a step-difference caused by the bank thickness T1 of the pixel definition layer PDL when the organic light emitting layer EL is formed by the transfer printing method.

The common electrode CE is disposed on the organic light emitting layer EL. Accordingly, the pixel is realized in the first pixel area PA1 in which the first pixel electrode PE1, the organic light emitting layer EL, and the common electrode CE are disposed, and another pixel is realized in the second pixel area PA2 in which the second pixel electrode PE2, the organic light emitting layer EL, and the common electrode CE are disposed.

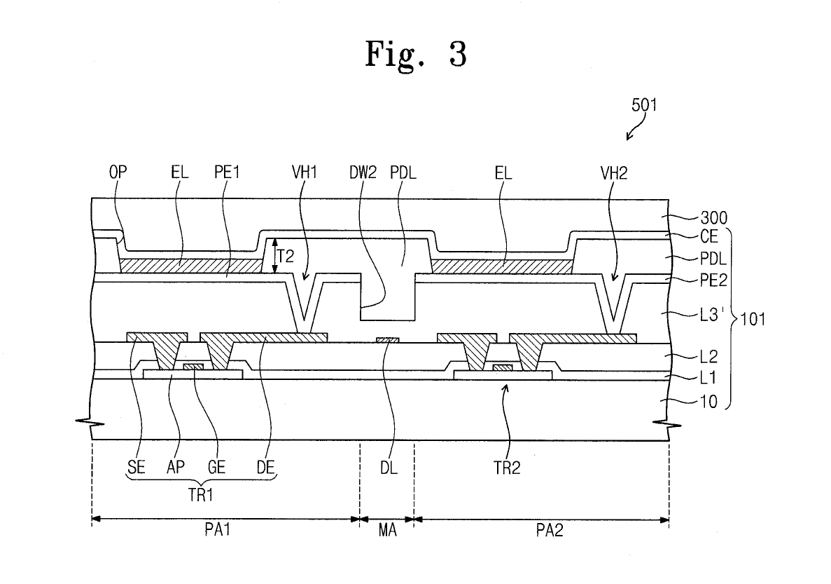

FIG. 3 is a cross-sectional view showing an organic electroluminescent display according to another exemplary embodiment of the present invention. In FIG. 3, the same reference numerals denote the same elements in FIGS. 1, 2A, and 2B, and thus detailed descriptions of the same elements will be omitted.

Referring to FIG. 3, the organic electroluminescent display 501 includes an insulating cover layer L3′, and the insulating cover layer L3′ is provided with a dummy well DW2 formed therethrough.

In the present exemplary embodiment, the dummy well DW2 is formed by removing an upper portion of the insulating cover layer L3 by a predetermined depth. Accordingly, the portion of the pixel definition layer PDL is filled in the dummy well DW2, thereby reducing a bank thickness T2 of the pixel definition layer PDL.

In addition, the bank thickness T2 is easily controlled by adjusting the depth of the dummy well DW2. For instance, when assuming that the bank thickness T2 is about 1,500 angstroms (0.15 μm), the bank thickness T2 is reduced in a ranged from about 1,000 angstroms (0.1 μm) to about 1,500 angstroms (0.15 μm) as the depth of the dummy well DW2 is increased. In addition, the bank thickness T2 is increased in a range from about 1,500 angstroms (0.15 μm) to about 3,000 angstroms (0.3 μm) as the depth of the dummy well DW2 is decreased.

FIGS. 4A to 4E are cross-sectional views showing a method of manufacturing the organic electroluminescent display shown in FIG. 2A. In FIGS. 4A to 4E, the same reference numbers denote the same elements in FIGS. 1, 2A, and 2B, and thus detailed descriptions of the same elements will be omitted.

Referring to FIG. 4A, the first and second driving transistors TR1 and TR2 are formed on the substrate 10, and the insulating cover layer L3, which is provided with the first and second via holes VH1 and VH2 formed therethrough, is formed on the first and second driving transistors TR1 and TR2.

Then, a conductive layer PE0 is formed on the insulating cover layer L3. Accordingly, the conductive layer PE0 makes contact with the drain electrode DE of the first driving transistor TRI through the first via hole VH1 and with the drain electrode DE of the second driving transistor TR2 through the second via hole VH2.

Referring to FIG. 4B, a mask pattern MP is formed on the conductive layer PE0. The mask pattern MP is formed to correspond to the first and second pixel areas PA1 and PA2 and opened in the non-pixel area MA. In the present exemplary embodiment, the mask pattern MP is formed by forming a photoresist layer on the conductive layer PE0 and exposing and developing the photoresist layer.

After the mask pattern MP is formed, the conductive layer PE0 is etched using the mask pattern MP as an etch mask, and thus the first pixel electrode PE1 and the second pixel electrode PE2 are formed. In detail, a portion of the conductive layer PE0, which corresponds to the non-pixel area MA, is removed through the etching process, so that the first and second pixel electrodes PE1 and PE2 are formed in the first and second pixel areas PA1 and PA2, respectively.

Referring to FIG. 4C, the insulating cover layer L3 is etched using the mask pattern MP as an etch mask. As a result, the portion of the insulating cover layer L3, which corresponds to the non-pixel area MA, is etched, and thus the dummy well DW1 is formed. In the present exemplary embodiment, the insulating cover layer L3 is etched by an ashing process with oxygen-containing gas to form the dummy well DW1.

Meanwhile, the mask pattern MP is used as the etch mask not only to etch the conductive layer but also to form the dummy well DW1 in the insulating cover layer L3 through the ashing process. Accordingly, because the mask pattern MP is used as the etch mask to perform the etching process and the ashing process, an additional etch mask is not required to perform the etching and ashing processes.

Referring to FIG. 4D, after the mask pattern MP shown in FIG. 4C is removed, the pixel definition layer PDL provided with the opening OP formed therethrough is formed on the insulating cover layer L3. The pixel definition layer PDL is formed by coating an organic material on the insulating cover layer L3 using a slit coating method or a spin coating method, curing the organic material to form an organic layer, and removing a portion of the organic layer corresponding to the first and second pixel definition layer PDL. In this process, the portion of the pixel definition layer PDL is filled in the dummy well DW1.

In general, when the organic layer is formed by coating the organic material on the substrate using the slit coating method or the spin coating method curing the coated organic material, the organic layer is required to have a thickness of about at least one micrometer, thereby securing the uniformity of the thickness of the organic layer. Accordingly, when the dummy well DW1 is not formed in the insulating cover layer PDL, the pixel definition layer PDL has the thickness of at least one micrometer so as to secure the uniformity of the thickness of the pixel definition layer PDL. In this case, since the pixel definition layer PDL has the thickness equal to or greater than one micrometer, the organic light emitting layer EL may not be easily formed due to the step-difference caused by the pixel definition layer PDL, which is formed by the transfer printing method. However, in the present exemplary embodiment, the dummy well DW1 is formed in the insulating cover layer L3 and the portion of the pixel definition layer PDL is filled in the dummy well DW1. Thus, the bank thickness T1 of the pixel definition layer PDL is reduced in a range from about 1,000 angstroms (0.1 μm) to about 3,000 angstroms (0.3 μm), thereby easily forming the organic light emitting layer using the transfer printing method.

Referring to FIG. 4E, a donor film DS on which the organic light emitting layer EL is formed is prepared and the donor film DS is attached to the pixel definition layer PDL and the first and second pixel electrodes PE1 and PE2, which are positioned at the uppermost position of the substrate 10. Then, a laser light LL is irradiated to transfer the organic light emitting layer EL to the first and second pixel electrodes PE1 and PE2 from the donor film DS, so that the organic light emitting layer EL is formed on the first and second pixel electrodes PE1 and PE2.

The donor film DS should be stably attached to the pixel definition layer

PDL and the first and second pixel electrodes PE1 and PE2 in order to improve the transfer quality of the organic light emitting layer EL. To this end, the step-difference caused by the pixel definition layer PDL, i.e., the bank thickness T1, is required to be small, and thus the donor film DS may be stably attached to the pixel definition layer PDL and the first and second pixel electrodes PE1 and PE2. According to the present exemplary embodiment, the bank thickness T1 of the pixel definition layer PDL may be controlled to be small, so that the transfer quality of the organic light emitting layer EL may be improved when the organic light emitting layer EL is formed using the transfer printing method.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed, and their equivalents.

What is claimed is:

1. An organic electroluminescent display comprising:
a substrate having a plurality of pixel areas and a non-pixel area;
pixel electrodes located at respective ones of the pixel areas;
driving transistors electrically connected to respective ones of the pixel electrodes;
an insulating cover layer that covers the driving transistors and has a dummy well located at a portion of the insulating cover layer corresponding to the non-pixel area;
a pixel definition layer on the insulating cover layer and having openings formed therethrough corresponding to the pixel areas, respectively, a portion of the pixel definition layer filling the dummy well;
an organic light emitting layer on the pixel electrodes; and
a common electrode on the organic light emitting layer.

2. The organic electroluminescent display of claim 1, wherein the dummy well is formed through the insulating cover layer.

3. The organic electroluminescent display of claim 1, wherein the dummy well is formed by removing a portion of the insulating cover layer by a predetermined depth.

4. The organic electroluminescent display of claim 3, wherein the pixel definition layer disposed on the insulating cover layer has a bank thickness that is decreased as the predetermined depth is increased.

5. The organic electroluminescent display of claim 4, wherein the bank thickness is in a range from about 0.1 μm to about 0.3 μm.

6. A method of manufacturing an organic electroluminescent display, comprising:
preparing a substrate having a plurality of pixel areas and a non-pixel area;
forming driving transistors on the substrate;
forming an insulating cover layer on the substrate to cover the driving transistors, the insulating cover layer being provided with via holes to expose a portion of the driving transistors;
forming pixel electrodes in the pixel areas to be electrically connected to respective ones of the driving transistors;
removing a portion of the insulating cover layer corresponding to the non-pixel area to form a dummy well;
forming a pixel definition layer on the insulating cover layer, a portion of the pixel definition layer being filled in the dummy well, the pixel definition layer having openings to expose at least a portion of the pixel electrodes;
forming an organic light emitting layer on the exposed at least the portion of the pixel electrodes; and
forming a common electrode on the organic light emitting layer.

7. The method of claim 6, wherein the forming of the pixel electrodes comprises:
forming a conductive layer making contact with the driving transistors through the via holes formed through the insulating cover layer;
forming a mask pattern on the conductive layer to correspond to the pixel areas; and
etching a portion of the conductive layer corresponding to the non-pixel area by using the mask pattern as an etch mask, and the insulating cover layer is etched using the mask pattern as an etch mask to form the dummy well.

8. The method of claim 7, wherein the dummy well is formed by etching the insulating cover layer using an ashing process.

9. The method of claim 6, wherein the dummy well is formed penetrating through the insulating cover layer.

10. The method of claim 6, wherein the dummy well is formed by removing a portion of the insulating cover layer by a predetermined depth.

11. The method of claim 10, wherein the pixel definition layer disposed on the insulating cover layer has a bank thickness that is decreased as the predetermined depth is increased.

12. The method of claim 11, wherein the bank thickness is in a range from about 0.1 μm to about 0.3 μm.

13. The method of claim 6, wherein the forming of the organic light emitting layer on the exposed pixel electrodes comprises:
attaching the substrate on which the pixel definition layer is formed to a donor substrate on which the organic light emitting layer is formed; and
heating the organic light emitting layer formed on the donor substrate to transfer the organic light emitting layer to the substrate on which the pixel definition layer is formed from the donor substrate.
